(19) United States
(12) Patent Application Publication
(10) Pub. No.: US 2017/0211450 A1
(43) Pub. Date: Jul. 27, 2017

(54) POWER GENERATOR FOR VEHICLE

(71) Applicant: TOYOTA JIDOSHA KABUSHIKI KAISHA, Toyota-shi (JP)

(72) Inventor: Kazuhiro SUGIMOTO, Susono-shi (JP)

(73) Assignee: TOYOTA JIDOSHA KABUSHIKI KAISHA, Toyota-shi (JP)

(21) Appl. No.: 15/370,449

(22) Filed: Dec. 6, 2016

(30) Foreign Application Priority Data
Jan. 25, 2016 (JP) 2016-011689

(51) Int. Cl. F01N 5/02; H01L 35/32; H01L 35/22; H01L 35/30

(52) U.S. Cl. CPC F01N 5/025; H01L 35/30; H01L 35/32; H01L 35/22

(57) ABSTRACT

A power generator includes thermoelectric transducers configured so that the band gap energy of an intrinsic semiconductor part disposed between an n-type semiconductor part and a p-type semiconductor part is lower than each band gap energy of the n-type semiconductor part and the p-type semiconductor part. The power generator is used in a vehicle that includes an exhaust pipe in which exhaust gas that supplies heat to the thermoelectric transducers flows. The thermoelectric transducers are installed in the exhaust pipe in such a manner that the surface of the intrinsic semiconductor part is opposed to the flow of the exhaust gas.

### CROSS-REFERENCE TO RELATED APPLICATION

This application is based on and claims the benefit of Japanese Patent Application No. 2016-011689, filed on Jan. 25, 2016, which is incorporated by reference herein in its entirety.

### BACKGROUND

Technical Field

The present disclosure relates to a power generator for a vehicle, and more particularly to a power generator for a vehicle that incorporates a thermoelectric transducer.

Background Art

There are various thermoelectric transducers based on the Seebeck effect. For such a thermoelectric transducer to produce an electromotive voltage, there needs to be a temperature difference between the two kinds of metals or semiconductors forming the thermoelectric transducer. Thus, power generation using the thermoelectric transducer requires a device that maintains the temperature difference, such as a cooler. WO 2015125823 A1 discloses a semiconductor single crystal that can be used as a thermoelectric transducer capable of generating power without the temperature difference.

Specifically, the semiconductor single crystal disclosed in WO 2015125823 A1 includes an n-type semiconductor part, a p-type semiconductor part, and an intrinsic semiconductor part disposed between the n-type semiconductor part and the p-type semiconductor part, and the band gap energy of the intrinsic semiconductor part is set to be lower than each band gap energy of the n-type semiconductor part and the p-type semiconductor part. If the semiconductor single crystal having this configuration is heated to fall within a predetermined temperature range, electrons in the valence band of the intrinsic semiconductor part is excited into the conduction band, even if there is no temperature difference between the n-type semiconductor part and the p-type semiconductor part. The electrons excited into the conduction band moves to the n-type semiconductor part, which has a lower energy, and the holes formed in the valence band moves to the p-type semiconductor part, which has higher energy. As a result of these movements, the carriers (electron and holes) are unevenly distributed, and the semiconductor single crystal serves as a power generating material with the p-type semiconductor part serving as a positive electrode and the n-type semiconductor part serving as a negative electrode. The semiconductor single crystal having this configuration used as a thermoelectric transducer can generate electric power when the temperature of the thermoelectric transducer is within the predetermined temperature range, even if there is no temperature difference between the n-type semiconductor part and the p-type semiconductor part.

In addition to WO 2015125823 A1, JP 2004-011512A is a patent document which may be related to the present disclosure.

### SUMMARY

In order to effectively use the heat produced in a vehicle, such as an automobile, the semiconductor single crystal disclosed in WO 2015125823 A1 as a thermoelectric transducer can be installed in a fluid that flows through some kind of flow channel of the vehicle. The flow velocity or temperature of the fluid may transiently vary depending on a request from a driver of the vehicle or other various requests. When the flow velocity or temperature of the fluid transiently varies depending on a request from a driver or another request, heat transfer to each of the n-type semiconductor part, the p-type semiconductor part and the intrinsic semiconductor part is not uniform and, as a result, a temperature difference may be produced between these parts. If, as a result of the temperature difference as just described being produced, the temperature of the n-type semiconductor part 12a or the p-type semiconductor part 12b having a relatively higher band gap energy becomes higher than the temperature of the intrinsic semiconductor part, it becomes difficult to efficiently produce the electromotive voltage of the thermoelectric transducer having the configuration disclosed in WO 2015125823 A1. As a result, efficient power generation may be difficult to be achieved using this thermoelectric transducer.

The present disclosure has been made to address the problem described above, and an object of the present disclosure is to provide a power generator for a vehicle, which includes a thermoelectric transducer configured so that the band gap energy of an intrinsic semiconductor part disposed between an n-type semiconductor part and a p-type semiconductor part is lower than each band gap energy of the n-type semiconductor part and the p-type semiconductor part, and in which the thermoelectric transducer is installed in a flow channel of the vehicle in such a manner as to efficiently generate electric power.

A power generator for a vehicle according to the present disclosure includes a thermoelectric transducer including an n-type semiconductor part, a p-type semiconductor part, and an intrinsic semiconductor part disposed between the n-type semiconductor part and the p-type semiconductor part. A band gap energy of the intrinsic semiconductor part is lower than each band gap energy of the n-type semiconductor part and the p-type semiconductor part. The power generator is used in a vehicle that includes a flow channel in which a fluid that supplies heat to the thermoelectric transducer flows. The thermoelectric transducer is installed in the flow channel in such a manner that a surface of the intrinsic semiconductor part is opposed to a flow of the fluid.

The power generator may further include a high band gap energy shield installed so as to cover a surface of a high band gap energy part of the thermoelectric transducer, at least on an upstream side in a flow direction of the fluid. The intrinsic semiconductor part may not correspond to the high band gap energy part, and an end portion of the n-type semiconductor part on a side opposite to the intrinsic semiconductor part and an end portion of the p-type semiconductor part of on a side opposite to the intrinsic semiconductor part may correspond to the high band gap energy part.

The thermoelectric transducer may include a plurality of thermoelectric transducers. The plurality of thermoelectric transducers may be configured as a transducer stack with the plurality of thermoelectric transducers electrically connected to each other with an electrode interposed therebetween. Where an end portion of the n-type semiconductor part of the thermoelectric transducer on a side opposite to the intrinsic semiconductor part is referred to as a first end portion and an end portion of the p-type semiconductor part of the thermoelectric transducer on a side opposite to the intrinsic semiconductor part is referred to as a second end portion, the electrode electrically may connect the first end portion of one of adjacent thermoelectric transducers and the second end portion of a rest of the adjacent thermoelectric transducers. The power generator may further include an electrode shield installed so as to cover a surface of the electrode, at least on an upstream side in a flow direction of the fluid.

The electrode shield may be configured to cover the electrode in such a manner as to be in contact with the electrode and configured to have a lower thermal conductivity than that of the electrode.

The power generator may further include a high band gap energy shield installed so as to cover a surface of a high band gap energy part of the thermoelectric transducer, at least on an upstream side in the flow direction of the fluid. The intrinsic semiconductor part may not correspond to the high band gap energy part, and the first end portion and the second end portion may correspond to the high band gap energy part.

The high band gap energy shield may be configured to cover the high band gap energy part in such a manner as to be in contact with the high band gap energy part and configured to expose the surface of the intrinsic semiconductor part to the fluid and configured to have a lower thermal conductivity than that of the thermoelectric transducer.

The transducer stack may include a plurality of unit stacks, each unit stack being configured with the plurality of thermoelectric transducers stacked with the electrode interposed therebetween. The plurality of unit stacks may be installed in such a manner that a stacking direction of the thermoelectric transducers included in each of the plurality of unit stacks aligns with a first perpendicular direction that is perpendicular to the flow direction of the fluid. The plurality of unit stacks may be arranged so as to be spaced by a predetermined distance from each other. Where a direction that is perpendicular to both of the flow direction of the fluid and the first perpendicular direction is referred to as a second perpendicular direction, the high band gap energy shield may be configured so as to extend in a plate shape along at least one of the flow direction of the fluid and the second perpendicular direction and configured so as to cover the high band gap energy shield of one or more thermoelectric transducers that are located so as to overlap with the high band gap energy shield.

The electrode shield and the high band gap energy shield may be integrally formed with each other.

The thermoelectric transducer may have a shape of a prism or a column that includes a side surface including the surface of the intrinsic semiconductor part, an end portion of the n-type semiconductor part on a side opposite to the intrinsic semiconductor part and an end portion of the p-type semiconductor part on a side opposite to the intrinsic semiconductor part. The thermoelectric transducer may be installed in the flow channel in such a manner that a heat flux received from the fluid by the side surface is greater than a heat flux received from the fluid by each of the end portion of the n-type semiconductor part and the end portion of the p-type semiconductor part.

The flow channel may be an inner channel of an exhaust pipe of an internal combustion engine mounted on the vehicle, and the fluid may be exhaust gas that flows in the exhaust pipe.

According to the power generator for a vehicle of the present disclosure, the thermoelectric transducer configured so that the band gap energy of the intrinsic semiconductor part disposed between the n-type semiconductor part and the p-type semiconductor part is lower than the band gap energy of the n-type semiconductor part and the p-type semiconductor part, and the thermoelectric transducer is installed in the flow channel in such a manner that the surface of the intrinsic semiconductor part is opposed to the flow of the fluid. Since, in the periphery of the surface of the surface of the thermoelectric transducer that is opposed to the flow of the fluid, the flow of the fluid is enhanced due to the collision of the fluid to the surface that is opposed to the flow of the fluid, heat transfer from the fluid to the thermoelectric transducer is facilitated. According to the method of installation, the surface of the intrinsic semiconductor part is included in this kind of surface opposed to the flow of the fluid. As a result, a temperature difference is less likely to be produced in such a manner that the temperature of the n-type semiconductor part or the p-type semiconductor part having a relatively higher band gap energy is higher than the temperature of the intrinsic semiconductor part, and the thermoelectric transducer can efficiently produce the electromotive voltage. Thus, efficient power generation can be achieved.

### BRIEF DESCRIPTION OF THE DRAWINGS

FIG. 1 is a diagram showing an application example of a power generator for a vehicle according to a first embodiment of the present disclosure;

FIG. 2 is a schematic perspective view showing a configuration of each thermoelectric transducer of the power generator shown in FIG. 1;

FIGS. 3A and 3B are conceptual diagrams showing statuses of the band gap energy of the thermoelectric transducer shown in FIG. 2;

FIG. 4 is a graph showing a relation between an electromotive voltage and the temperature of the thermoelectric transducer;

FIG. 5 is a perspective diagram showing an example of a configuration of a transducer stack according to the first embodiment of the present disclosure;

FIG. 6 is a schematic diagram for explaining a method of installing the transducer stack shown in FIG. 5 with respect to the flow of exhaust gas;

FIGS. 7A to 7E are diagrams for supplementally explaining what a surface S of the thermoelectric transducer is;

FIGS. 8A and 8B are diagrams for illustrating an advantage of the manner of installation of the thermoelectric transducers according to the first embodiment;

FIG. 9 is a schematic view for explaining an overall configuration of a power generator for a vehicle according to a second embodiment of the present disclosure;

FIGS. 10A and 10B are diagrams for explaining an advantage of the arrangement of electrodes according to the second embodiment;

FIGS. 11A and 11B are diagrams for explaining modification examples of the configuration of an electrode according to the present disclosure;

FIG. 12 is a schematic view for explaining an overall configuration of a power generator for a vehicle according to a third embodiment of the present disclosure;

FIG. 13 is a schematic perspective view showing a configuration around a transducer stack shown in FIG. 12;

FIG. 14 is a diagram for explaining a first modification example of a configuration concerning a high band gap energy shield according to the present disclosure;

FIG. 15 is a diagram for explaining a first modification example of a configuration concerning a high band gap energy shield according to the present disclosure;

FIG. 16 is a diagram for explaining a second modification example of a configuration concerning a high band gap energy shield according to the present disclosure; and

FIG. 17 is a diagram for illustrating another manner of stacking of the thermoelectric transducers shown in FIG. 2.

### DETAILED DESCRIPTION

In the following, embodiments of the present disclosure will be described with reference to the drawings. In the drawings, the same reference numerals denote the same or similar components.

### First Embodiment

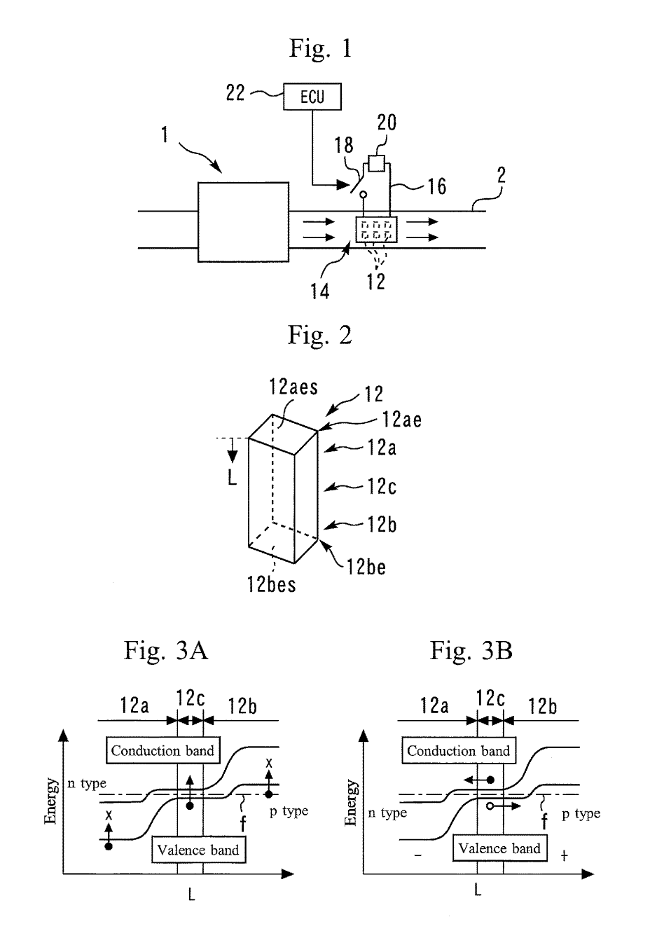

First, with reference to FIGS. 1 to 8, a first embodiment of the present disclosure will be described. FIG. 1 is a diagram showing an application example of a power generator 10 for a vehicle according to the first embodiment of the present disclosure. FIG. 2 is a schematic perspective view showing a configuration of each thermoelectric transducer 12 of the power generator 10 shown in FIG. 1.

### [Installation Site of Power Generator in Vehicle]

The installation site of heat transducers 12 which the power generator 10 according to the present embodiment includes is not particularly limited, as far as thermoelectric transducers 12 are installed in some kind of flow channel of the vehicle. In the first embodiment, as shown in FIG. 1, the thermoelectric transducers 12 are arranged, for example, in an exhaust pipe 2 of an internal combustion engine 1 that is mounted on the vehicle. In other words, in the example shown in FIG. 1, the heat of high-temperature exhaust gas after combustion in a combustion chamber of the internal combustion engine 1 is supplied to the thermoelectric transducers 12. Examples of a fluid that flows through a flow channel of the vehicle and supplies heat to the thermoelectric transducers 12 include not only the exhaust gas but also an engine cooling water that flows through a cooling water flow channel for cooling of the internal combustion engine 1, and an engine oil that flows through an oil flow channel for lubrication of the internal combustion engine 1.

In the power generator 10 according to the present embodiment, the plurality of thermoelectric transducers 12 are installed in the exhaust gas in the form of a transducer stack 14, which is formed by the plurality of thermoelectric transducers 12 electrically connected to each other. Details of the configuration of the transducer stack 14 will be described later with reference to FIG. 5. The power generator 10 is provided with an electrical circuit 16 that is configured to connect the opposite ends of the transducer stack 14 by conductive wires. The electrical circuit 16 is opened and closed with a switch 18. Electrical equipment (such as a light) 20 mounted on the vehicle is connected to the electrical circuit 16. The switch 18 is opened and closed under the control of an electronic control unit (ECU) 22 mounted on the vehicle.

With the power generator 10 configured as described above, during activation of the vehicle system, the transducer stack 14 is enabled to generate power by closing the switch 18 when the temperature of the thermoelectric transducers 12 reaches a temperature suitable for power generation as a result of heat from the exhaust gas being supplied to the thermoelectric transducers 12. In the present embodiment, the fluid for supplying heat is the exhaust gas, so that the exhaust heat of the internal combustion engine 1 can be recovered by the power generation. In addition, the electric power obtained by the power generation by the transducer stack 14 can be supplied to the electrical equipment 20. The switch 18 may be replaced with a variable resistor. In this example, the electric power supplied from the transducer stack 14 to the electrical equipment 20 can be controlled in more detail by adjusting the resistance of the variable resistor. Vehicle equipment that receives the electric power is not limited to the electrical equipment 20, and a battery that accumulates electric power may be connected to the electrical circuit 16 instead of or in addition to the electrical equipment 20, for example.

### [Configuration of Thermoelectric Transducer]

In the example shown in FIG. 2, the thermoelectric transducer 12 has the shape of a prism. The thermoelectric transducer 12 has an n-type semiconductor part 12a at one end and a p-type semiconductor part 12b at the other end. The thermoelectric transducer 12 further has an intrinsic semiconductor part 12c between the n-type semiconductor part 12a and the p-type semiconductor part 12b.

FIGS. 3A and 3B are conceptual diagrams showing statuses of the band gap energy of the thermoelectric transducer 12 shown in FIG. 2. In FIGS. 3A and 3B, the vertical axes indicate the energy of an electron, and the horizontal axes indicate the distance L (see FIG. 2) from an end face 12aes of the thermoelectric transducer 12 on the side of the n-type semiconductor part 12a.

As shown in FIGS. 3A and 3B, in the n-type semiconductor part 12a, the Fermi level f is in the conduction band, and in the p-type semiconductor part 12b, the Fermi level f is in the valence band. In the intrinsic semiconductor part 12c, the Fermi level f is at the middle of the forbidden band existing between the conduction band and the valence band. The band gap energy corresponds to the difference in energy between the uppermost part of the valence band and the lowermost part of the conduction band. As can be seen from these drawings, the band gap energy of the intrinsic semiconductor part 12c of the thermoelectric transducer 12 is lower than the band gap energies of the n-type semiconductor part 12a and the p-type semiconductor part 12b. Note that the length ratio between the n-type semiconductor part 12a, the p-type semiconductor part 12b and the intrinsic semiconductor part 12c shown in FIGS. 3A and 3B is just an example, and the ratio can vary depending on how the thermoelectric transducer (semiconductor single crystal) 12 is formed. The band gap energy of the n-type semiconductor part 12a, the p-type semiconductor part 12b and the intrinsic semiconductor part 12c can be measured in inverse photoelectron spectroscopy, for example.

The thermoelectric transducer (semiconductor single crystal) 12 having the characteristics described above (that is, the band gap energy of the intrinsic semiconductor part 12c is lower than the band gap energies of the n-type semiconductor part 12a and the p-type semiconductor part 12b) can be made of a clathrate compound (inclusion compound), for example. As an example of the clathrate compound, a silicon clathrate Ba₈Au₈Si₃₈ may be used.

The thermoelectric transducer 12 according to the present embodiment can be manufactured in any method, as far as the method can produce the thermoelectric transducer 12 having the characteristics described above. If the thermoelectric transducer 12 is made of, for example, the silicon clathrate Ba₈Au₈Si₃₈, the manufacturing method described in detail in International Publication No. WO 2015125823 A1 can be used, for example. The manufacturing method can be summarized as follows. That is, Ba powder, Au powder and Si powder are weighed in the ratio (molar ratio) of 8:8:38. The weighed powders are melted together by arc melting. The melt is then cooled to form an ingot of the silicon clathrate Ba₈Au₈Si₃₈. The ingot of the silicon clathrate Ba₈Au₈Si₃₈ prepared in this way is crushed into grains. The grains of the silicon clathrate Ba₈Au₈Si₃₈ are melted in a crucible in the Czochralski method, thereby forming a single crystal of the silicon clathrate Ba₈Au₈Si₃₈. The thermoelectric transducer 12 shown in FIG. 2 is provided by cutting the single crystal of the silicon clathrate Ba₈Au₈Si₃₈ prepared in this way into the shape of a prism (more specifically, the shape of a rectangular parallelepiped). The shape of the thermoelectric transducer is not limited to the rectangular parallelepiped, and the thermoelectric transducer may have any shape provided by cutting the single crystal into a desired shape, such as a cube or a column.

### [Principle of Power Generation]

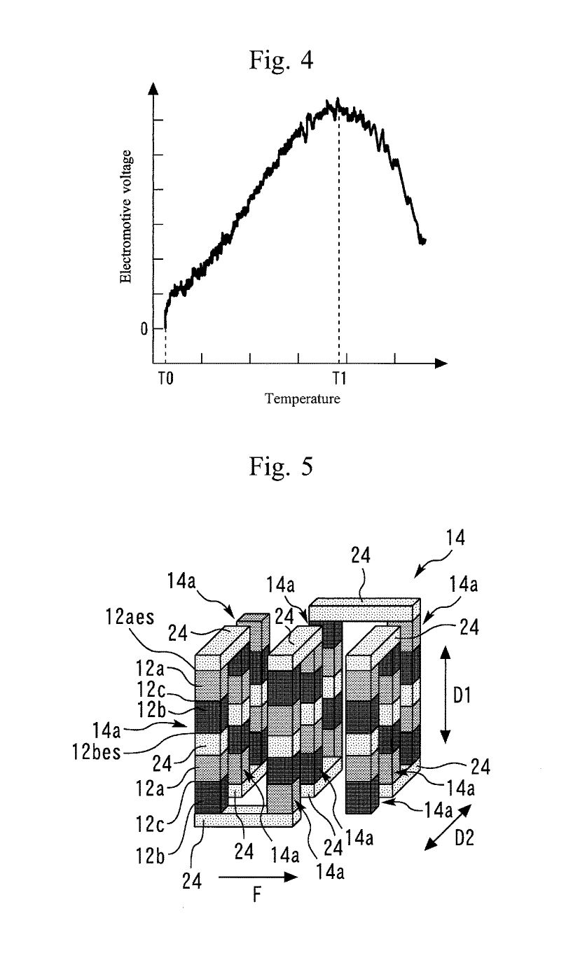

FIG. 3A is a conceptual diagram showing a status of thermal excitation of the thermoelectric transducer 12 when the thermoelectric transducer 12 is heated to a predetermined temperature. If the thermoelectric transducer 12 is heated to a temperature T0 (see FIG. 4 described later) or higher, electrons (shown by black dots) in the valence band are thermally excited into the conduction band, as shown in FIG. 3A. More specifically, if heat is supplied and energy exceeding the band gap energy is thereby supplied to an electron located in an uppermost part of the valence band, the electron is excited into the conduction band. In the process where the temperature of the thermoelectric transducer 12 increases, a condition can occur in which such thermal excitation of electrons occurs only in the intrinsic semiconductor part 12c, which has a relatively low band gap energy. FIG. 3A shows a status of the thermoelectric transducer 12 in which the thermoelectric transducer 12 is heated to a predetermined temperature (such as the temperature T0) that can allow such a condition to occur. In this status, no electrons are thermally excited in the n-type semiconductor part 12a and the p-type semiconductor part 12b, which have a relatively higher band gap energy.

FIG. 3B is a conceptual diagram showing movement of an electron (shown by the black dot) and a hole (shown by a white dot) when the thermoelectric transducer 12 is heated to the predetermined temperature described above. As shown in FIG. 3B, electrons excited into the conduction band move toward a part of lower energy, that is, toward the n-type semiconductor part 12a. On the other hand, holes formed in the valence band as a result of the electrons being excited move toward a part of higher energy, that is, toward the p-type semiconductor part 12b. The carriers are unevenly distributed in this way, so that the n-type semiconductor part 12a is negatively charged, and the p-type semiconductor part 12b is positively charged, and therefore, an electromotive force occurs between the n-type semiconductor part 12a and the p-type semiconductor part 12b. Thus, the thermoelectric transducer 12 can generate power even if there is no temperature difference between the n-type semiconductor part 12a and the p-type semiconductor part 12b. This principle of power generation differs from the Seebeck effect, which produces an electromotive force based on a temperature difference. The power generator 10 using the thermoelectric transducer 12 requires no temperature difference and therefore a cooling part that provides the temperature difference and therefore can be simplified in configuration.

FIG. 4 is a graph showing a relation between an electromotive voltage and the temperature of the thermoelectric transducer 12. The term “electromotive voltage” of the thermoelectric transducer 12 used herein refers to the potential difference between an end portion of the thermoelectric transducer 12 on the side of the p-type semiconductor part 12b serving as a positive electrode and an end portion of the thermoelectric transducer 12 on the side of the n-type semiconductor part 12a serving as a negative electrode. More specifically, the relation shown in FIG. 4 shows temperature characteristics of the electromotive voltage produced when the thermoelectric transducer 12 is heated in such a manner that no temperature difference is produced between the n-type semiconductor part 12a and the p-type semiconductor part 12b. Note that the temperature range in which the electromotive voltage is produced differs depending on the composition of the thermoelectric transducer.

As shown in FIG. 4, the electromotive voltage is produced when the thermoelectric transducer 12 is heated to the temperature T0 or higher. More specifically, as the temperature of the thermoelectric transducer 12 increases, the electromotive voltage also increases. A possible reason why the electromotive voltage increases as the temperature increases as shown in FIG. 4 is that, as the amount of heat supplied increases, the number of electrons and holes that can be excited in the intrinsic semiconductor part 12c, which has a relatively low band gap energy, increases. As shown in FIG. 4, the electromotive voltage reaches a peak value at a certain temperature T1 and decreases as the thermoelectric transducer 12 is further heated beyond the temperature T1. A possible reason for this is that, as the temperature of the thermoelectric transducer 12 increases, not only electrons and holes in the intrinsic semiconductor part 12c but also electrons and holes in the n-type semiconductor part 12a and the p-type semiconductor part 12b are thermally excited.

[Method of Installing Thermoelectric Transducer (Transducer Stack) with respect to Direction of Flow of Exhaust Gas]

As can be seen from FIG. 4 described above, power generation by using the thermoelectric transducer 12 is possible if the temperature of the thermoelectric transducer 12 falls within a predetermined range. More favorably, efficient power generation is possible if the temperature of the thermoelectric transducer 12 is close to the temperature T1 at which the peak electromotive voltage is achieved. Thus, to achieve efficient power generation using the thermoelectric transducers 12 on the vehicle, a fluid, which can supply heat to the thermoelectric transducers 12 so that the temperature of each of the thermoelectric transducers 12 approaches a temperature suitable for power generation, is selected from among various flow channels of the vehicle, and the thermoelectric transducers 12 are installed in the selected fluid. More specifically, the temperature of the exhaust gas in the exhaust pipe 2 decreases as it flows downstream. When the exhaust gas is used as the fluid that serves as the heat source as in the present embodiment, the installation site of the thermoelectric transducer 12 in the exhaust pipe 2 along the direction of flow of the exhaust gas is determined so that a heat source that allows efficient power generation is provided.

(Issue with Efficient Power Generation)

As described above, the thermoelectric transducer 12 is configured to produce an electromotive voltage as a result of the movement of electrons and holes caused by the electrons in the intrinsic semiconductor part 12c being thermally excited when the thermoelectric transducer 12 is supplied with heat from the fluid. To achieve efficient power generation using the thermoelectric transducers 12, it is useful to meet the following requirements concerning the installation of the thermoelectric transducers 12 (transducer stack 14) with respect to the flow direction of the exhaust gas.

It can be said that, under a steady flow of heat in which the flow velocity and temperature of a fluid (in the present embodiment, exhaust gas) that serves as a heat source are steadily constant, the temperature of each part of the thermoelectric transducer 12 that is supplied with heat from the fluid approaches a constant value with lapse of time. However, the flow velocity or temperature of a fluid of the vehicle may transiently vary depending on a request from a driver of the vehicle or other various requests. When the flow velocity or temperature of the fluid transiently varies as just described, heat transfer to each part of the n-type semiconductor part 12a, the p-type semiconductor part 12b and the intrinsic semiconductor part 12c is not uniform and, as a result, a temperature difference may be produced between these parts. If a temperature difference is produced in the thermoelectric transducer 12 in such a manner that the temperature of the intrinsic semiconductor part 12c is higher than the temperature of the n-type semiconductor part 12a and the p-type semiconductor part 12b, thermal excitation of electrons in the intrinsic semiconductor part 12c is promoted compared with thermal excitation of electrons in the n-type semiconductor part 12a and the p-type semiconductor part 12b. This is favorable, rather than an issue. However, depending on the installation of the thermoelectric transducer 12 with respect to the fluid, a temperature difference may be likely to be produced in such a manner that the temperature of one or both of the n-type semiconductor part 12a and the p-type semiconductor part 12b is higher than the temperature of the intrinsic semiconductor part 12c. As the temperature difference in this manner increases, electrons are more easily thermally excited in the one or both of the n-type semiconductor part 12a and the p-type semiconductor part 12b. This may make it harder for the thermoelectric transducer 12 to produce the electromotive voltage. As a result, efficient power generation may be difficult to be achieved.

Based on the reason described above, it is favorable that power generation and heat recovery accompanying the power generation by thermoelectric transducers in the actual vehicle environments can be efficiently performed not only under a steady flow of heat but also under a flow of heat in which the flow velocity or temperature of the fluid varies as described above. In addition, to achieve this, it is effective to make it harder for a temperature difference to be produced in such a manner that the temperature of one or both of the n-type semiconductor part 12a and the p-type semiconductor part 12b is higher than the temperature of the intrinsic semiconductor part 12c.

(Method of Installing Thermoelectric Transducer (Transducer Stack) according to First Embodiment)

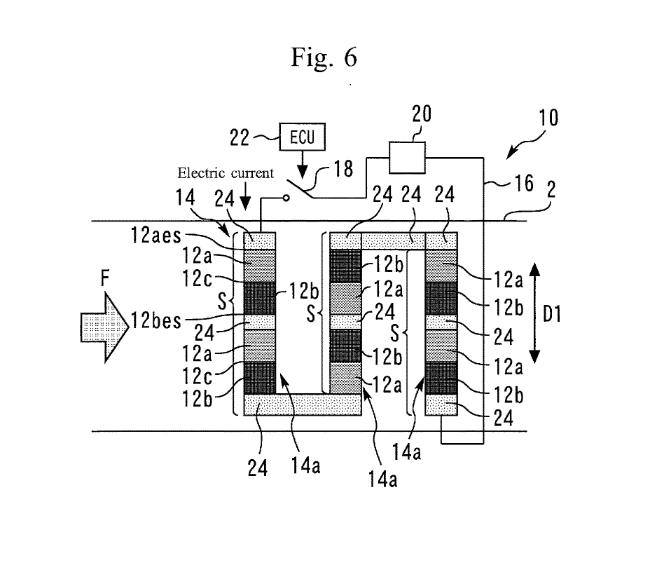

In view of the above description, according to the present embodiment, the transducer stack 14, which is a stack of thermoelectric transducers 12, is installed in the exhaust pipe 2 (that is, in the flow of the exhaust gas) in the arrangement shown in FIGS. 5 and 6 described below.

FIG. 5 is a perspective diagram showing an example of a configuration of the transducer stack 14 according to the first embodiment of the present disclosure. FIG. 6 is a schematic diagram for explaining a method of installing the transducer stack 14 shown in FIG. 5 with respect to the flow of the exhaust gas. In FIG. 5 and other drawings, for the sake of clarity of the arrangement of the thermoelectric transducers 12 (this similarly applies to a thermoelectric transducer 62), the n-type semiconductor part 12a and the p-type semiconductor part 12b of the thermoelectric transducer 12 are distinguished by color. The intrinsic semiconductor part 12c between the n-type semiconductor part 12a and the p-type semiconductor part 12b lies around the boundary between the parts 12a and 12b. Note that, although the illustration of the transducer stack 14 is omitted in FIG. 6, the transducer stack 14 is fixed to the inner wall of the exhaust pipe 2 with an attachment not shown in the drawing.

As shown in FIG. 5, the plurality of thermoelectric transducers 12 that form the transducer stack 14 are connected in series with each other with an electrode 24 interposed between adjacent thermoelectric transducers 12. That is, the transducer stack 14 includes the thermoelectric transducers 12 and the electrodes 24. The electrode 24 may be made of a metal material, such as copper, that has low electrical resistance. According to the principle of power generation of the thermoelectric transducer 12 described above, the p-type semiconductor part 12b serves as a positive electrode, and the n-type semiconductor part 12a serves as a negative electrode. Therefore, an electric current caused by the electromotive force produced by power generation flows in a direction F from the p-type part to the n-type part. In the present embodiment, in order to ensure that the electric current smoothly flows while maximizing the potential difference between the opposite ends of the electrode 24, the electrode 24 is configured to connect an end portion 12ae (see FIG. 2) of the n-type semiconductor part 12a on the opposite side to the intrinsic semiconductor part 12c of one thermoelectric transducer 12 and an end portion 12be (see FIG. 2) of the p-type semiconductor part 12b on the opposite side to the intrinsic semiconductor part 12c of another thermoelectric transducer 12 to each other. In other words, the electrode 24 is configured to connect parts having the highest band gap energy to each other.

More specifically, the surface of the end portion 12ae of the n-type semiconductor part 12a includes an end face 12aes and a portion of the side surface of the n-type semiconductor part 12a that is close to the end face 12aes. Similarly, the surface of the end portion 12be of the p-type semiconductor part 12b includes an end face 12bes and a portion of the side surface of the p-type semiconductor part 12b that is close to the end face 12bes. In the example shown in FIG. 5, the electrode 24 connects the end face 12aes and the end face 12bes to each other. However, according to the present disclosure, any electrode that connects the end portions of adjacent thermoelectric transducers (that is, connects a first end portion (the end portion of the n-type semiconductor part on the opposite side to the intrinsic semiconductor part) and a second end portion (the end portion of the p-type semiconductor part on the opposite side to the intrinsic semiconductor part)) to each other can be used. Thus, as an alternative to the example described above, the electrode 24 may be configured to connect the portion of the side surface of the n-type semiconductor part 12a that is close to the end face 12aes and the portion of the side surface of the p-type semiconductor part 12b that is close to the end face 12bes to each other.

In the transducer stack 14, each part having the shape of a rod is herein referred to as a “unit stack 14a”. The plurality of (nine in the example shown in FIG. 5) unit stacks 14a are installed in such a manner that the stacking direction of the thermoelectric transducers 12 included in each unit stack 14a aligns with a first perpendicular direction D1 that is perpendicular to the flow direction F of the exhaust gas. In addition, the plurality of unit stacks 14a are arranged so as to be spaced by a predetermined distance from each other (spaced equally from each other, for example). More specifically, adjacent unit stacks 14a spaced by the predetermined distance are connected with each other with the electrode 24 interposed therebetween in a form that the directions of the positive electrode and negative electrode are changed alternately. In order to maximizing heat of the exhaust gas supplied to the unit stacks 14a arranged on the downstream side of the exhaust gas flow, it is favorable that the exhaust gas flows through spaces between the unit stacks 14a arranged in line along the flow direction F of the exhaust gas. The predetermined distance is therefore set as a distance needed for ensuring this kind of flow of the exhaust gas.

In addition to the above, in the example shown in FIGS. 5 and 6, the unit stacks 14a are installed in line along the flow direction F of the exhaust gas (in three rows along the flow direction F in the example of the present embodiment) and in line (in three rows, for example) also along a second perpendicular direction D2 that is perpendicular to the flow direction F of the exhaust gas and the first perpendicular direction D1. The way of stacking of the thermoelectric transducers 12 is not particularly limited. In the transducer stack 14, the thermoelectric transducers 12 are stacked in series with each other in such a way that, as shown in FIG. 5, the unit stacks 14a are folded in a serpentine form with each other with the electrode 24 interposed therebetween. With the transducer stack 14, by appropriately determining the number of thermoelectric transducers 12 stacked, any desired level of electromotive voltage can be produced under the temperature condition of the thermoelectric transducers 12 expected from the heat supply from the exhaust pipe 2.

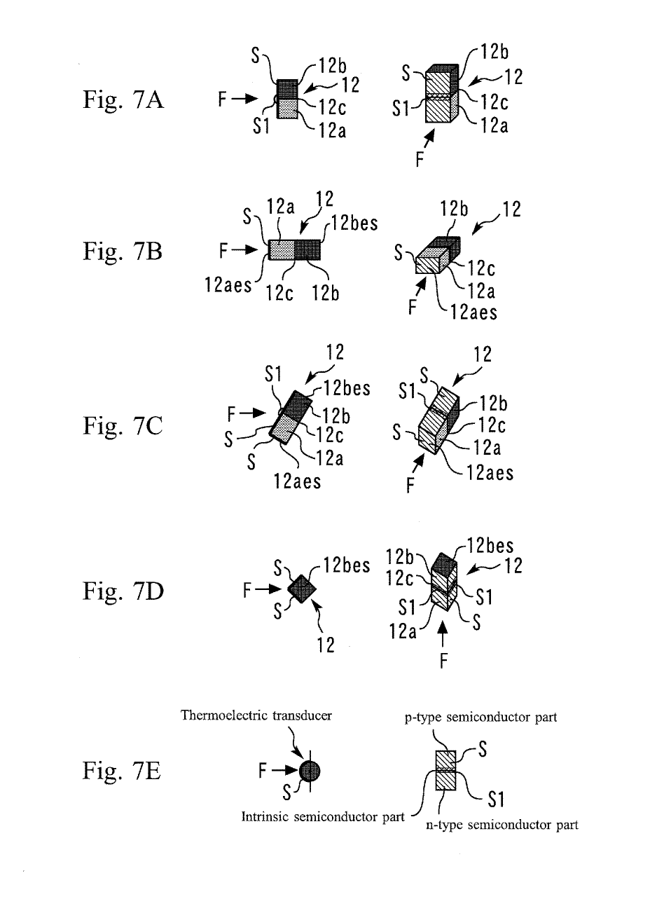

According to the transducer stack 14 installed as shown in FIGS. 5 and 6, each thermoelectric transducer 12 is disposed in the exhaust pipe 2 in such a way that the surface of the intrinsic semiconductor part 12c is opposed to the flow of the exhaust gas (more specifically, a way that a portion of the surface of the intrinsic semiconductor part 12c is included in a surface S which is a portion of the surface of the thermoelectric transducer 12 and which is opposed to the flow of the exhaust gas). In the present embodiment, as already described, the thermoelectric transducers 12 have the shape of a prism (more specifically, the shape of a rectangular parallelepiped), for example. Therefore, a side surface (see FIG. 7A described below) of each thermoelectric transducer 12 that faces on the upstream side of the exhaust gas flow corresponds to the surface S of each thermoelectric transducer 12.

FIGS. 7A to 7E are diagrams for supplementally explaining what the surface S of the thermoelectric transducer 12 is. Thick lines and hatching areas shown in each of FIGS. 7A to 7E represent the surface S that is opposed to the flow of the exhaust gas. Firstly, FIG. 7A includes a side view and a perspective view that indicate the thermoelectric transducer 12 installed in the same manner as that shown in FIG. 6. In the example shown in FIG. 7A, a portion Si of the surface of the intrinsic semiconductor part 12c is included in the surface S.

Next, FIG. 7B includes a side view and a perspective view that indicate an example of installing the thermoelectric transducer 12 in such a manner that the end face 12aes of the n-type semiconductor part 12a is opposed to the flow direction F of the exhaust gas. Since the end portion 12aes corresponds to the surface S in this example, a portion of the surface of the intrinsic semiconductor part 12c is not included in the surface S. This also applies to an arrangement in which the end face 12bes of the p-type semiconductor part 12b is opposed to the flow direction F of the exhaust gas.

Next, FIG. 7C includes a side view and a perspective view that indicate an example of installing the thermoelectric transducer 12 in such a manner that the thermoelectric transducer 12 is inclined with respect to the flow direction F of the exhaust gas (in other words, a manner that the thermoelectric transducer 12 arranged as shown in FIG. 7A is rotated with the axis line of the second perpendicular direction D2 as a center). In this example, one side surface and one end face 12aes of the thermoelectric transducer 12 correspond to the surface S. Therefore, in this example, a portion Si of the surface of the intrinsic semiconductor part 12c is included in the surface S as with the example shown in FIG. 7A. Note that, if the installation positions of the n-type semiconductor part 12a and p-type semiconductor part 12b are opposite to those of the example shown in FIG. 7C, one side surface and one end face 12bes of the thermoelectric transducer 12 correspond to the surface S.

Next, FIG. 7D includes views (more specifically, a view as seen from a direction perpendicular to the end face 12bes and a perspective view) that indicate another example of installing the thermoelectric transducer 12 in such a manner that the thermoelectric transducer 12 is inclined with respect to the flow direction F of the exhaust gas (in other words, a manner that the thermoelectric transducer 12 arranged as shown in FIG. 7A is rotated with the axis line of the first perpendicular direction D1 as a center). In this example, two side surfaces of the thermoelectric transducer 12 on the upstream side of the flow direction F of the exhaust gas correspond to the surface S. Therefore, in this example, again, a portion Si of the surface of the intrinsic semiconductor part 12c is included in the surface S.

Next, FIG. 7E includes views (more specifically, a view as seen from a direction perpendicular to an end face of an n-type semiconductor part or a p-type semiconductor part and a view as seen from the flow direction F of the exhaust gas) that indicate an example of a thermoelectric transducer that has the shape of a column and that is installed in the same orientation as that shown in FIG. 7A. In this example, a semicircular column part of the thermoelectric transducer on the opposite side of the flow of the exhaust gas corresponds to the surface S. Therefore, in this example, a portion Si of the surface of an intrinsic semiconductor part is included in the surface S as with the example shown in FIG. 7A.

With reference to FIG. 6, again, explanation on the configuration of the present embodiment is continued. The surface S opposed to the flow of the exhaust gas is easy to be warmed when the thermoelectric transducer 12 is subjected to the exhaust gas whose temperature is higher than that of the thermoelectric transducer 12 itself. This is because, in the periphery of the surface S that is opposed to the exhaust gas, the turbulence (flow) of the exhaust gas is enhanced due to the collision of the exhaust gas to the surface S, heat transfer from the exhaust gas to the thermoelectric transducer 12 is facilitated with an enhancement of this turbulence (flow). This effect is achieved not only the thermoelectric transducers 12 of the unit stacks 14a in the first row on the upstream side of the exhaust gas but also the thermoelectric transducers 12 of the unit stacks in the second and third rows. This is because the exhaust gas which has passed through the periphery of the unit stacks 14a in the first row flows toward each surface S of the unit stacks 14a in the second and third lows. Based on the above, it can be said that, when a heat flux (amount of heat passing through a unit area per unit time) received by each part of the thermoelectric transducer 12 from the exhaust gas is taken into consideration, the manner of the installation of each thermoelectric transducer 12 according to the present embodiment allows a heat flux received from the exhaust gas by a side surface of the thermoelectric transducer 12 corresponding to the surface S to be greater than a heat flux received from the exhaust gas by each of the end face 12aes of the n-type semiconductor part 12a and the end face 12bes of the p-type semiconductor part 12b having the highest band gap energies. This applies to not only a configuration in which the thermoelectric transducers 12 have the shape of a rectangular parallelepiped as in the present embodiment but also a configuration in which a thermoelectric transducer has any shape, such as a cube that is one example of a prism, or a column.

### [Advantage of Method of Installing Thermoelectric Transducer (Transducer Stack) According to First Embodiment]

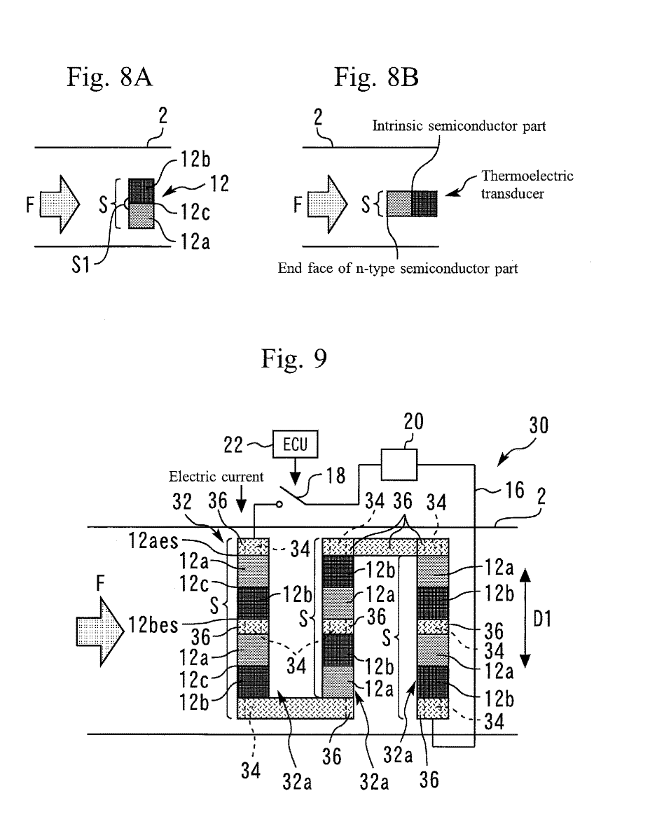

FIGS. 8A and 8B are diagrams for illustrating an advantage of the manner of installation of the thermoelectric transducers 12 according to the first embodiment. FIG. 8B shows a thermoelectric transducer installed in a method other than the method according to the present disclosure. More specifically, in the installation method shown in FIG. 8B, the surface of the intrinsic semiconductor part is not included in the surface S that corresponds to a portion easy to be warmed (that is, a portion having the highest heat transfer coefficient), as with the example shown in FIG. 7B. In the example shown in FIG. 8B, a portion corresponding to the surface S is a portion having the highest band gap energy (in this example, the end face of the n-type semiconductor part). Because of this, the surface of the intrinsic semiconductor part having a relatively low band gap energy is harder to allow heat transfer from the exhaust gas to be facilitated as compared with the aforementioned end face having the highest band gap energy. As a result, a temperature difference is likely to be produced in such a manner that the temperature of the n-type semiconductor part having a relatively high band gap energy is higher than the temperature of the intrinsic semiconductor part, and it may become difficult to efficiently provide an electromotive voltage of the thermoelectric transducer.

On the other hand, FIG. 8A shows the thermoelectric transducer 12 installed in the manner according to the present embodiment, as with the configuration shown in FIG. 6. According to this kind of configuration, since a portion of the surface of the intrinsic semiconductor part 12c is included in the surface S that is a portion easy to be warmed (that is, a portion having the highest heat transfer coefficient), heat transfer from the exhaust gas can be easy to be facilitated on the surface of the intrinsic semiconductor part 12c. This makes it harder for a temperature difference in the manner described above to be produced, and an electromotive voltage of the thermoelectric transducer 12 can therefore be produced efficiently. As a result, even if the flow velocity or the temperature of the exhaust gas which is the heat source transiently varies depending on, for example, a request from a driver of the vehicle, efficient power generation can be achieved using this thermoelectric transducer.

Note that the thermoelectric transducer 12 installed in the flow of the exhaust gas may be oriented as shown in FIG. 7C or 7D, instead of the example shown in FIG. 7A according to the first embodiment described above. In addition, as already described, the shape of a thermoelectric transducer according to the present disclosure is not limited to the shape of a rectangular parallelepiped, and may be a cube or a column, for example. If a thermoelectric transducer having the shape of a cube is installed, the orientation of installation of the thermoelectric transducer may be determined as with the example shown in FIG. 7A, 7C or 7D. Furthermore, if a thermoelectric transducer having the shape of a column is installed, the orientation of installation of the thermoelectric transducer may be determined as with the example shown in FIG. 7E, or the thermoelectric transducer may be installed in such a manner as to be included with respect to the flow direction F of the exhaust gas as with the example shown in FIG. 7C.

### Second Embodiment

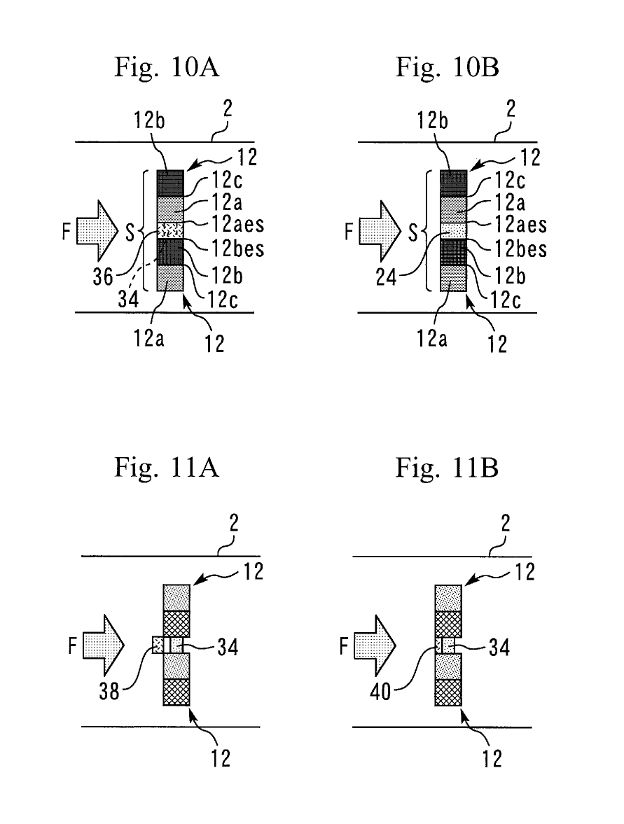

Next, with reference to FIGS. 9 and 10, a second embodiment of the present disclosure will be described.

FIG. 9 is a schematic view for explaining an overall configuration of a power generator 30 for a vehicle according to the second embodiment of the present disclosure. The power generator 30 according to the present embodiment includes a transducer stack 32 having a plurality of unit stacks 32a. As shown in FIG. 9, a plurality of thermoelectric transducers 12 forming each unit stack 32a are connected in series with each other with an electrode 34 interposed between every adjacent two of the thermoelectric transducers 12. The stacking pattern of the transducer stack 32 is the same as that of the transducer stack 14 according to the first embodiment, for example. The power generator 30 differs from the power generator 10 according to the first embodiment in arrangement of the electrodes 34. The following description will be focused on the difference.

As shown in FIG. 9, the power generator 30 includes a shield 36 for each electrode 34 that connects adjacent thermoelectric transducers 12. Each of the shields 36 is provided in such a way as to cover not only the surface of a portion of the electrode 34 on the upstream side of the exhaust gas but also cover the whole of the surface of the electrode 34. More specifically, in the example shown in FIG. 9, each of the shields 36 covers the electrode 34 in such a way that the whole of the inner surface of the shield 36 is in contact with the whole of the surface of the electrode 34 that corresponds thereto. The shields 36 have a lower thermal conductivity than those of both of the electrode 34 and the thermoelectric transducer 12. Specifically, the shields 36 may be made of a ceramic material, for example. That is, the shields 36 of the present embodiment serve as a heat insulator.

FIGS. 10A and 10B are diagrams for explaining an advantage of the arrangement of the electrodes 34 according to the second embodiment. FIG. 10B shows the arrangement of the electrode 24 according to the first embodiment. In this arrangement, the electrode 24 is in direct contact with the exhaust gas. Therefore, in this arrangement, the surface of the electrode 24 also corresponds to a portion of the surface S (that is, a part easy to be warmed) described above. The electrode 24 made of metal basically has a higher thermal conductivity than the thermoelectric transducer 12. Therefore, with the arrangement shown in FIG. 10B, the electrode 24 has a stronger tendency to receive heat from the exhaust gas than the thermoelectric transducer 12. Because of this, in the process where the amount of heat supplied to the transducer stack 14 is increasing due to an increase in the temperature of the exhaust gas, the temperature of the electrode 24 is easily increased prior to the temperature of the thermoelectric transducer 12. As a result, the heat supplied to the electrode 24 is easily transferred to the parts of the thermoelectric transducer 12 that are in contact with the electrode 24 (that is, the end faces 12aes and 12bes of the n-type semiconductor part 12a and the p-type semiconductor part 12b having the highest band gap energy).

On the other hand, in the arrangement according to the present embodiment shown in FIG. 10A, there is the shield 36 between the electrode 34 and the exhaust gas. Since the surface of the electrode 34 on the upstream side of the exhaust gas is covered by the shield 36 with this kind of arrangement, heat transfer from the exhaust gas to the electrode 34 can be avoided from being facilitated due to the collision of the flow of the exhaust gas to the electrode 34.

Further, each of the shields 36 according to the present embodiment cover the electrode 34 in such a manner that the whole of the inner surface of the shield 36 is in contact with the whole of the surface of the electrode 34 that corresponds thereto. In contrast to this configuration, if the shield 36 is apart from the electrode 34, the heat of the exhaust gas may be transferred to the electrode 34 due to the exhaust gas flowing through the spaces between the shield 36 and the electrode 34. According to the present configuration, however, the heat transfer in this manner can also be reduced. Further, the thermal conductivity of the shield 36 is lower than that of the electrode 34. Thus, the heat conduction from the shield 36 to the electrode 34 can also be reduced. As a result, heat input from the electrode 34 to the n-type semiconductor part 12a and the p-type semiconductor part 12b can be reduced. As a result, a temperature difference is less likely to be produced in such a manner that the temperature of the n-type semiconductor part 12a or the p-type semiconductor part 12b is higher than the temperature of the intrinsic semiconductor part 12c. Thus, efficient power generation can be achieved. In addition, in the present embodiment, the thermal conductivity of the shield 36 is lower than that of the thermoelectric transducer 12. Therefore, heat input from the shield 36 to the thermoelectric transducer 12 can also be reduced.

A shield for reducing heat input to the electrode 34 (which corresponds to an “electrode shield” according to the present disclosure) may be, for example, configured as follows, instead of the shield 36 according to the second embodiment described above. FIGS. 11A and 11B are diagrams for explaining modification examples of the configuration of an electrode according to the present disclosure.

First, in the configuration shown in FIG. 11A, a shield 38 is installed in such a manner as not to cover the whole of the surface of the electrode 34 and to cover the surface of the electrode 34 at a location on the upstream side of the exhaust gas that is easy to be warmed due to a reason that the location is opposed to the flow of the exhaust gas. In other words, the shield 38 is installed in such a manner as not to be in contact with the electrode 34. The electrode shield according to the present disclosure may be installed, as with the shield 38, in such a manner as to cover only a portion of the surface of an electrode on the upstream side of the flow direction of the fluid. Since this kind of configuration can also prevent the flow of the exhaust gas from directly coming into collision with the electrode 34, the heat transfer from the exhaust gas to the electrode 34 can be prevented from being facilitated due to this kind of collision of the exhaust gas. Note that the shield 38 is fixed to the thermoelectric transducer 12 or the exhaust pipe 2 with an attachment not shown in the drawing.

Moreover, although a shield 40 shown in FIG. 11B also covers the surface of the electrode 34 at only a part thereof on the upstream side of the exhaust gas, the shield 40 cover the electrode 34 in such a manner as to be in contact with the electrode 34. Because of this, in the example of this shield 40, the shield 40 is configured as a heat insulator, as with the shield 36 according to the second embodiment, in order to reduce the heat conduction from the shield 40 to the electrode 34, contrary to the shield 38 shown in FIG. 11A. According to the configuration shown in FIG. 11B, heat input to the electrode 34 due to the exhaust gas flowing through the spaces between the shield 40 and the electrode 34 can be avoided more effectively than the configuration shown in FIG. 11A, and the heat conduction from the shield 40 to the electrode 34 can also be reduced. Consequently, the configuration shown in FIG. 11B can reduce heat input to the electrode 34 more effectively than the configuration shown in FIG. 11A.

### Third Embodiment

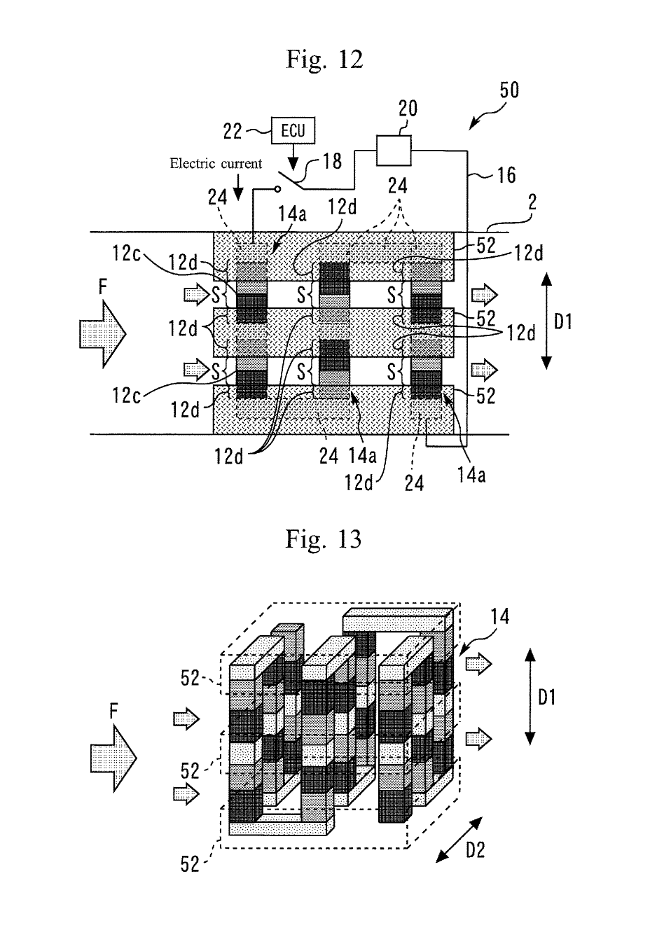

Next, with reference to FIGS. 12 and 13, a third embodiment of the present disclosure will be described.

FIG. 12 is a schematic view for explaining an overall configuration of a power generator 50 for a vehicle according to the third embodiment of the present disclosure. FIG. 13 is a schematic perspective view showing a configuration around the transducer stack 14 shown in FIG. 12. The power generator 50 according to the present embodiment includes the transducer stack 14 as in the first embodiment.

As shown in FIG. 12, a portion that is specified so as not to include the intrinsic semiconductor part 12c and to include the end portion 12ae of the n-type semiconductor part 12a and the end portion 12be of the p-type semiconductor part 12b (both of which are parts having the highest band gas energy) is herein referred to as a high band gap energy part (hereunder, mainly abbreviated to a “high BE part”) 12d.

The unit stack 14a is a stack of a plurality of (two, for example) thermoelectric transducers 12. The power generator 50 includes nine unit stacks 14a, for example. These unit stacks 14a are arranged so as to be spaced by a predetermined distance from each other along each of the flow direction F of the exhaust gas and the second perpendicular direction D2 as shown in FIGS. 12 and 13. Further, the transducer stack 14 is configured in such a manner that the positions of the thermoelectric transducers 12 (and the electrodes 24) which these unit stacks 14a include are aligned with each other along the first perpendicular direction D1.

The transducer stack 14 of the power generator 50 according to the present embodiment includes shields 52. For the transducer stake 14 that has the configuration described above, each of the shields 52 is configured so as to cover the high BE part of each of the thermoelectric transducers 12 that are located so as to overlap with the shields 52 in the first perpendicular direction D1 and configured so as to extend in a plate shape along both of the flow direction F of the exhaust gas and the second perpendicular direction D2. More specifically, the shields 52 are configured so as to be divided into three in such a manner as to extend parallel to both of the flow direction F of the exhaust gas and the second perpendicular direction D2 in association with the above-described configuration of the transducer stack 14.

According to the shields 52 having the configuration described above, each of the high BE parts 12d of the thermoelectric transducers 12 of the transducer stack 14 is covered therewith at not only the surface of a portion of each high BE part 12d on the upstream side of the exhaust gas but also the whole of the surface of each high BE part 12d. More specifically, each of the shields 52 covers the whole of the surface of each high BE part 12d in such a manner as to be in contact with the surface of each high BE part 12d, and exposes each intrinsic semiconductor part 12c and its vicinity (that is, parts other than each high BE part 12d) to the exhaust gas. In addition, since the shields 52 are in contact with the high BE parts 12d, the shields 52 are configured to have a lower thermal conductivity than that of the thermoelectric transducer 12. Specifically, the shields 52 can be made of a material (such as ceramics).

Further, in contrast to the second embodiment described above in which each of the shields 36 covers only the electrode 34, each of the shields 52 according to the present embodiment covers both of the electrode 24 and the high BE part 12d of each thermoelectric transducer 12. That is, in the present embodiment, an electrode shield for the electrode 24 and a high band gap energy shield (which corresponds to a “high band gap energy shield”) for the high BE part 12d are integrally formed with each other.

More specifically, the shields 52 cover the electrodes 24 and the high BE parts 12d of the n-type semiconductor parts 12a and the p-type semiconductor parts 12b that are connected to the electrodes 24. The shields 52 cover the electrodes 24 in such a manner as to be in contact therewith. Therefore, the shields 52 are configured using a material (as an example, ceramics as described above) having a lower thermal conductivity than not only that of the thermoelectric transducer 12 but also that of the electrode 24.

A part of the flow channel of the exhaust pipe 2 is blocked by the shields 52 having the configuration described so far, and, as a result, the channel cross-sectional area of the exhaust pipe 2 is made smaller. As described above, the intrinsic semiconductor parts 12c and their vicinities expose to the exhaust gas without being covered by the shields 52. In other words, a part of the flow channel of the exhaust pipe 2 is blocked by the shields 52 in such a way that the periphery of the intrinsic semiconductor parts 12c and their vicinities are ensured as a flow channel of the exhaust gas.

According to the configuration of the present embodiment which includes the shields 52, the exhaust gas can be prevented from colliding with the high BE parts 12d. As a result, heat transfer caused by the turbulence (flow) of the exhaust gas in the periphery of the high BE parts 12d can be prevented from being facilitated. In addition, according to this configuration, the exhaust gas the flow velocity of which is increased by reducing the channel cross-sectional area with the shields 52 is allowed to collide with the intrinsic semiconductor parts 12c and their vicinities that have a relatively low band gap energy. As a result, the flow of a high velocity exhaust gas can be produced in the periphery of the intrinsic semiconductor parts 12c and their vicinities. Therefore, the heat transfer can be facilitated at the intrinsic semiconductor parts 12c and their vicinities. In this way, according to this configuration, the heat from the exhaust gas can be transferred intensively at the intrinsic semiconductor parts 12c and their vicinities. Accordingly, an occurrence of a temperature difference in the manner described above can be reduced more reliably as compared with the configuration of the second embodiment.

Furthermore, each of the shields 52 of the present embodiment covers the high BE parts 12d in such a manner as to be in contact with the high. BE parts 12d. The heat of the exhaust gas can thus be prevented from being transferred due to the exhaust gas flowing through spaces between the shields 52 and the high BE parts 12d. This also applies to a relation between the shields 52 and the electrodes 24. Each of the shields 52 is configured to have a lower thermal conductivity than those of both of the thermoelectric transducer 12 and electrode 24. Accordingly, the heat conduction from the shields 52 to the high BE parts 12d and the electrodes 24 can also be reduced.

A high band gas energy shield, which is provided for facilitating the collision between the intrinsic semiconductor part 12c and a high velocity fluid while preventing the collision from the fluid to the high BE parts, may be configured as a shield 66 or 72 described below, for example, instead of the shield 52 of the third embodiment described above.

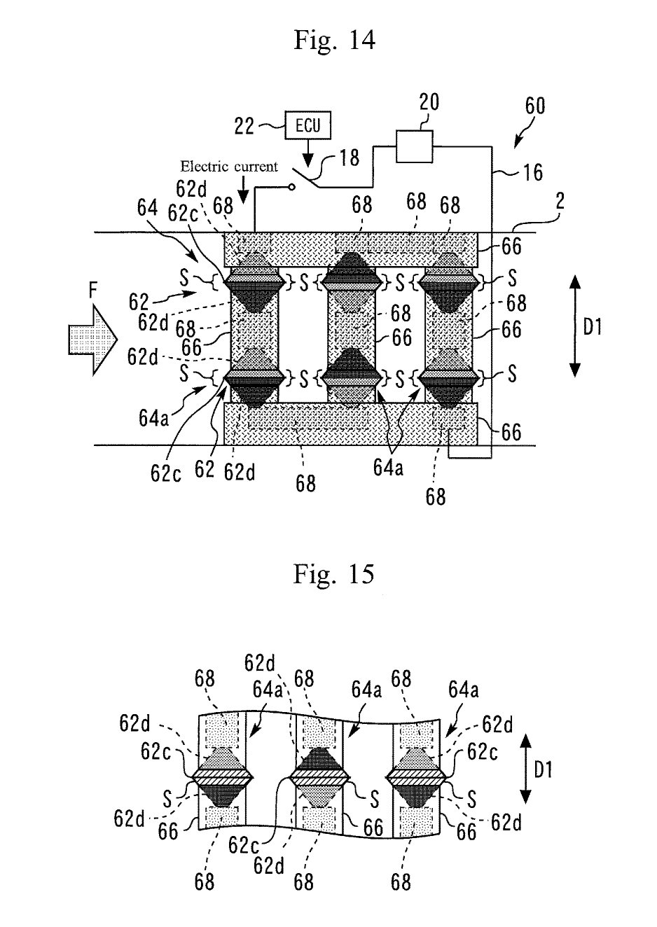

FIGS. 14 and 15 are diagrams for explaining a first modification example of a configuration concerning the high band gap energy shield according to the present disclosure. FIG. 14 shows a configuration of a power generator 60 according to the first modification example as seen from the same direction as in FIG. 12, and FIG. 15 shows a part of a transducer stack 64 shown in FIG. 14 as seen from the flow direction F of the exhaust gas.

The main difference between the first modification example and the third embodiment concerning a viewpoint other than the configuration of a shield is the shape of the thermoelectric transducer. More specifically, a plurality of thermoelectric transducers 62 forming the transducer stack 64 which the power generator 60 include are formed as a regular octahedron as can be seen from FIGS. 14 and 15. An intrinsic semiconductor part 62c of each of the thermoelectric transducers 62 is located at the junction of two quadrangular pyramids.

The stacking pattern of the transducer stack 64 is the same as that of the transducer stack 14, for example. The power generator 60 includes a plurality of shields 66. Some of the plurality of shields 66 are arranged for each unit stack 64 in a divided fashion, and are formed so as to extend along the stacking direction of each unit stack 64a (that is, the first perpendicular direction D1). In addition, the rest of the plurality of shields 66 are arranged at end portions of the transducer stack 64 in the first perpendicular direction D1 with a configuration similar to the shields 52 described above. Each of the shields 66 in the arrangement according to the first modification example is also configured, as with the shields 52 described above, to cover high BE parts 62d in such a manner as to be in contact with the high BE parts 62d and to expose the surface of each intrinsic semiconductor part 62c to the exhaust gas. Further, each of the shields 66 is configured to cover not only the high BE parts 62d but also electrodes 68 (that is, in such a manner as to be in contact with the electrodes 68). Furthermore, each of the shields 66 is configured to have a lower thermal conductivity than those of both of the thermoelectric transducer 62 and electrode 68. Specifically, the shields 66 can be made of a material, such as ceramics.

In the configuration according to the first modification example, a portion of the surface of each of the intrinsic semiconductor parts 62c is included in the surface S (see FIG. 15) that is a portion easy to be warmed (that is, a portion having the highest heat transfer coefficient), as with the configurations according to the first and second embodiments. In addition, according to the present configuration of the thermoelectric transducers 62 having the shape described above, the collision of a high velocity exhaust gas to the intrinsic semiconductor parts 62c can be facilitated while preventing the collision of the exhaust gas to the high BE parts 62d, as with the configuration according to the third embodiment.

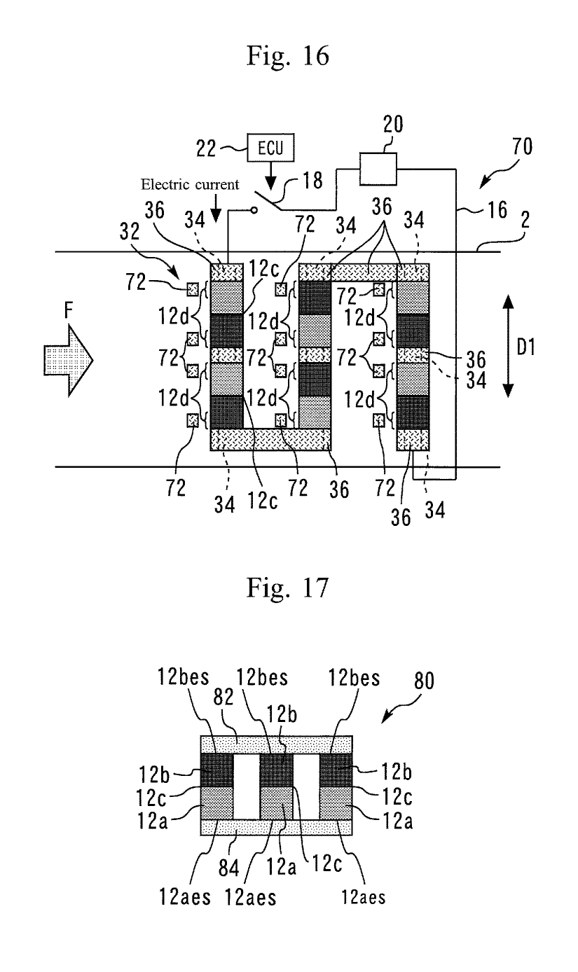

Next, FIG. 16 is a diagram for explaining a second modification example of a configuration concerning a high band gap energy shield according to the present disclosure. FIG. 16 shows a configuration of a power generator 70 according to the second modification example as seen from the same direction as in FIG. 12. Concerning a configuration other than a shield, the configuration of this power generator 70 is assumed to be basically the same as that of the power generator 30 according to the second embodiment.

In the power generator 70 shown in FIG. 16, each of shields 72 is installed so as not to entirely cover the surface of the high BE part 12d but also to cover the surface of the high BE part 12d at a location on the upstream side of the exhaust gas that is easy to be warmed due to a reason that the location is opposed to the flow of the exhaust gas. More specifically, each of the shields 72 is installed so as to cover the surface of the high BE part 12d in such a manner as not to be in contact with the high BE part 12d. The high band gap energy shield according to the present disclosure, such as this shield 72, may be installed so as to cover only a portion of the surface of the high band gap energy part on the upstream side of the flow direction of the fluid. Further, an electrode shield and a high band gap energy shield may be separated from each other, as with the configuration shown in FIG. 16. Further, only the high band gap energy shield may be provided for the thermoelectric transducer according to the present disclosure.

With the configuration shown in FIG. 16, again, the flow of the exhaust gas can be prevented from being directly collided with the high BE parts 12d. The heat transfer from the exhaust gas to the high BE parts can therefore be prevented from being facilitated due to this kind of collision with the exhaust gas. In addition, since the shields 72 are installed, the collision of a high velocity exhaust gas to the intrinsic semiconductor parts 12c can be facilitated. Note that each of the shields 72 is fixed to the thermoelectric transducer 12 or the exhaust pipe 2 with an attachment not shown in the drawing. Further, contrary to the present configuration, each of the shields 72 may be configured using a material that has a lower thermal conductivity than that of the thermoelectric transducer 12, and configured to cover the high BE part 12d in such a manner as to be in contact with the high BE part 12d.

In the third embodiment, the example in which the intrinsic semiconductor part 12c and its vicinity are present as a portion other than the high BE part 12d has been described. However, the high BE part that is an object for being covered by the high band gap energy shield may be all portions other than the intrinsic semiconductor part.

Moreover, in the transducer stack 14 exemplified in the third embodiment described above, the plurality of (as an example, three) unit stacks 14a are arranged so as to be spaced by a predetermined distance from each other in both of the flow direction F of the exhaust gas and the second perpendicular direction D2. If, contrary to this kind of arrangement, a plurality of unit stacks are arranged so as to be spaced by a predetermined distance from each other along any one of the flow direction F of the exhaust gas and the second perpendicular direction D2, the high band gap energy shield may be configured so as to extend along the flow direction F or the second perpendicular direction D2 along which a plurality of unit stacks are installed.

In the first to third embodiments and modification examples thereof described above, the power generator 10, 30, 50, 60 or 70 is provided with the transducer stack 14, 32 or 64 formed by a plurality of thermoelectric transducers 12 or 62. However, the present disclosure is not necessarily limited to the power generators including a plurality of thermoelectric transducers in the form of a transducer stack, and the power generator according to the present disclosure may include only one thermoelectric transducer that is installed in a flow channel in such a manner that the surface of the intrinsic semiconductor part is opposed to a flow of a fluid.

Furthermore, FIG. 17 is a diagram for illustrating another manner of stacking of the thermoelectric transducers 12 shown in FIG. 2. FIG. 17 shows a transducer stack 80 as seen from the flow direction F of the exhaust gas. In the configuration shown in FIG. 17, again, each thermoelectric transducer 12 forming the transducer stack 80 is arranged in the exhaust pipe in such a manner that the surface of the intrinsic semiconductor part 12c is opposed to the flow of the exhaust gas.

In the configuration shown in FIG. 17, end faces 12bes of the p-type semiconductor parts 12b serving as a positive electrode are electrically connected to each other by an electrode 82, and end faces 12aes of the n-type semiconductor part 12a serving as a negative electrode are electrically connected to each other by an electrode 84. The transducer stack of a plurality of thermoelectric transducers 12 is not limited to the stack including the thermoelectric transducers 12 connected in series with each other, such as those in the examples described above, and a stack including the thermoelectric transducers 12 connected in parallel with each other, such as the configuration shown in FIG. 17, is also possible. In addition, if a plurality of thermoelectric transducers 12 are stacked, a series connection of a plurality of thermoelectric transducers and a parallel connection of a plurality of thermoelectric transducers may be combined.

Note that, in order to suppress a leakage of the electric current from a thermoelectric transducer according to the present disclosure (for example, thermoelectric transducer 12) to a fluid that flows through a flow channel in which the thermoelectric transducer is installed, it may be needed to insulate the thermoelectric transducer from the fluid depending on the kind of the fluid. If this kind of insulation is needed, the surface of the thermoelectric transducer may be in contact with an insulator. In addition, a member other than the insulator, such as a protector (for example, a cover for the thermoelectric transducer) may be in contact with the surface of the thermoelectric transducer. Even in an example in which this kind of member is provided, the heat of the fluid is transferred to the thermoelectric transducer through any one or both of the insulator and the protector. Therefore, in this example, if the thermoelectric transducer is installed in the flow channel in such a manner that the intrinsic semiconductor part is opposed to the flow of the fluid, heat transfer from the fluid to the intrinsic semiconductor part can be facilitated as with the examples described above. Further, if a power generator includes a housing that houses the thermoelectric transducer, a part of the housing may be configured by the aforementioned cover.

The embodiments and modifications described above may be combined in other ways than those explicitly described above as required and may be modified in various ways without departing from the scope of the present disclosure.

What is claimed is:

1. A power generator for a vehicle, comprising:
a thermoelectric transducer including an n-type semiconductor part, a p-type semiconductor part, and an intrinsic semiconductor part disposed between the n-type semiconductor part and the p-type semiconductor part, a band gap energy of the intrinsic semiconductor part being lower than each band gap energy of the n-type semiconductor part and the p-type semiconductor part,
wherein the power generator is used in a vehicle that includes a flow channel in which a fluid that supplies heat to the thermoelectric transducer flows, and
wherein the thermoelectric transducer is installed in the flow channel in such a manner that a surface of the intrinsic semiconductor part is opposed to a flow of the fluid.

2. The power generator according to claim 1, further comprising a high band gap energy shield installed so as to cover a surface of a high band gap energy part of the thermoelectric transducer, at least on an upstream side in a flow direction of the fluid,
wherein the intrinsic semiconductor part does not corresponds to the high band gap energy part, and an end portion of the n-type semiconductor part on a side opposite to the intrinsic semiconductor part and an end portion of the p-type semiconductor part of on a side opposite to the intrinsic semiconductor part correspond to the high band gap energy part.

3. The power generator according to claim 1,
wherein the thermoelectric transducer includes a plurality of thermoelectric transducers,
wherein the plurality of thermoelectric transducers are configured as a transducer stack with the plurality of thermoelectric transducers electrically connected to each other with an electrode interposed therebetween,
wherein, where an end portion of the n-type semiconductor part of the thermoelectric transducer on a side opposite to the intrinsic semiconductor part is referred to as a first end portion and an end portion of the p-type semiconductor part of the thermoelectric transducer on a side opposite to the intrinsic semiconductor part is referred to as a second end portion, the electrode electrically connects the first end portion of one of adjacent thermoelectric transducers and the second end portion of a rest of the adjacent thermoelectric transducers, and
wherein the power generator further comprises an electrode shield installed so as to cover a surface of the electrode, at least on an upstream side in a flow direction of the fluid.

4. The power generator according to claim 3,
wherein the electrode shield is configured to cover the electrode in such a manner as to be in contact with the electrode and configured to have a lower thermal conductivity than that of the electrode.

5. The power generator according to claim 3, further comprising a high band gap energy shield installed so as to cover a surface of a high band gap energy part of the thermoelectric transducer, at least on an upstream side in the flow direction of the fluid,
wherein the intrinsic semiconductor part does not corresponds to the high band gap energy part, and the first end portion and the second end portion correspond to the high band gap energy part.

6. The power generator according to claim 5,
wherein the high band gap energy shield is configured to cover the high band gap energy part in such a manner as to be in contact with the high band gap energy part and configured to expose the surface of the intrinsic semiconductor part to the fluid and configured to have a lower thermal conductivity than that of the thermoelectric transducer.

7. The power generator according to claim 6,
wherein the transducer stack includes a plurality of unit stacks, each unit stack being configured with the plurality of thermoelectric transducers stacked with the electrode interposed therebetween,
wherein the plurality of unit stacks are installed in such a manner that a stacking direction of the thermoelectric transducers included in each of the plurality of unit stacks aligns with a first perpendicular direction that is perpendicular to the flow direction of the fluid,
wherein the plurality of unit stacks are arranged so as to be spaced by a predetermined distance from each other, and
wherein, where a direction that is perpendicular to both of the flow direction of the fluid and the first perpendicular direction is referred to as a second perpendicular direction, the high band gap energy shield is configured so as to extend in a plate shape along at least one of the flow direction of the fluid and the second perpendicular direction and configured so as to cover the high band gap energy shield of one or more thermoelectric transducers that are located so as to overlap with the high band gap energy shield.

8. The power generator according to claim 5,
wherein the electrode shield and the high band gap energy shield are integrally formed with each other.

9. The power generator according to claim 1,
wherein the thermoelectric transducer has a shape of a prism or a column that includes a side surface including the surface of the intrinsic semiconductor part, an end portion of the n-type semiconductor part on a side opposite to the intrinsic semiconductor part and an end portion of the p-type semiconductor part on a side opposite to the intrinsic semiconductor part, and
wherein the thermoelectric transducer is installed in the flow channel in such a manner that a heat flux received from the fluid by the side surface is greater than a heat flux received from the fluid by each of the end portion of the n-type semiconductor part and the end portion of the p-type semiconductor part.

10. The power generator for a vehicle according to claim 1,
wherein the flow channel is an inner channel of an exhaust pipe of an internal combustion engine mounted on the vehicle, and the fluid is exhaust gas that flows in the exhaust pipe.
